(19) United States
(12) Patent Application Publication
(10) Pub. No.: US 2025/0357398 A1
(43) Pub. Date: Nov. 20, 2025

(54) SELF-ALIGNED PATTERNING ON PACKAGE SUBSTRATE

(71) Applicant: Micron Technology, Inc., Boise, ID (US)

(72) Inventors: Bharat Bhushan, Taichung (TW); Kunal R. Parekh, Boise, ID (US); Akshay N. Singh, Boise, ID (US); Raj K. Bansal, Boise, ID (US)

(21) Appl. No.: 19/210,229

(22) Filed: May 16, 2025

Related U.S. Application Data
(60) Provisional application No. 63/649,085, filed on May 17, 2024.

(51) Int. Cl. H01L 23/00; H01L 25/18; H10D 80/30

(52) U.S. Cl. CPC H01L 24/08; H01L 24/48; H01L 25/18; H10D 80/30; H01L 2224/08145; H01L 2224/48249; H01L 2924/1438

(57) ABSTRACT

Systems, devices, and methods for self-aligned patterning for bonding semiconductor structures are provided herein. A semiconductor device assembly can include a first semiconductor structure and a second semiconductor structure bonded to the first semiconductor structure. The first semiconductor structure can have a first dimension and the second semiconductor structure can have a second dimension greater than the first dimension such that a probing pad of the second semiconductor structure, a side edge of a first dielectric layer of the first semiconductor structure, and a side edge of a second dielectric layer of the second semiconductor structure are exposed. The exposed side edge of the first dielectric layer and the exposed side edge of the second dielectric layer can form a continuous surface. In some embodiments, the continuous surface comprises an artifact of a fabrication method of the present technology.

### CROSS-REFERENCE TO RELATED APPLICATION(S)

The present application claims priority to U.S. Provisional Patent Application No. 63/649,085, filed May 17, 2024, the disclosure of which is incorporated herein by reference in its entirety.

### TECHNICAL FIELD

The present disclosure generally relates to semiconductor devices, and more particularly relates to self-aligned patterning on a substrate.

### BACKGROUND

Microelectronic devices generally have a die (i.e., a semiconductor chip) that includes integrated circuitry with a high density of circuit components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1A is a schematic, cross-sectional side view of an example first semiconductor structure.

FIG. 1B is a schematic, cross-sectional side view of an example second semiconductor structure.

FIG. 1C is a schematic, cross-sectional side view of an example semiconductor device assembly including the first semiconductor structure of FIG. 1A and the second semiconductor structure of FIG. 1B.

FIG. 2 is a schematic, cross-sectional side view of a semiconductor device assembly in accordance with embodiments of the present technology.

FIG. 3 is a schematic, cross-sectional side view of another semiconductor device assembly in accordance with embodiments of the present technology.

FIG. 4 is a schematic, cross-sectional side view of a packaged semiconductor device assembly in accordance with embodiments of the present technology.

FIGS. 5-8 are schematic, cross-sectional side views illustrating a series of fabrication steps of semiconductor device assemblies in accordance with embodiments of the present technology.

FIG. 9 is a flowchart illustrating a method of making a semiconductor device assembly in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

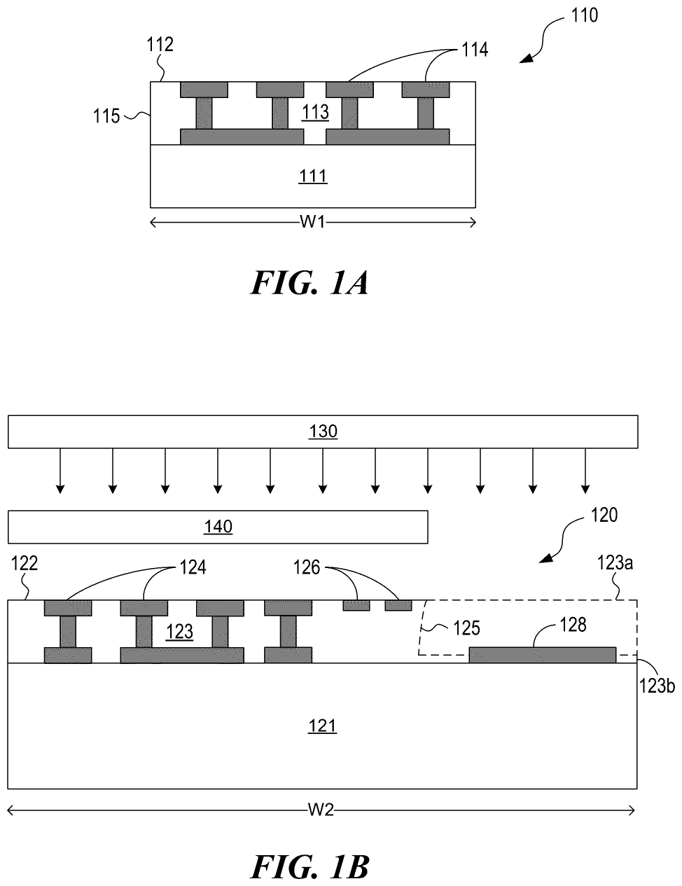

Some packaged semiconductor device assemblies include semiconductor structures (e.g., a chip, a wafer) stacked and bonded together. A first semiconductor structure and a second semiconductor structure can be prepared separately, then stacked together in a face-to-face, face-to-back, or other arrangement. The bond pads on each of the first and second semiconductor structures can be used to bond the first and second semiconductor structures together via, for example, hybrid bonding. One approach to fabricating a semiconductor device assembly is illustrated by way of example in FIGS. 1A-IC.

FIG. 1A is a schematic, cross-sectional side view of an example first semiconductor structure 110. The first semiconductor structure 110 includes a substrate 111 (e.g., a silicon substrate), a dielectric layer 113 (e.g., a silicon oxide layer) on the substrate 111, and a plurality of bond pads 114 (e.g., copper bond pads) embedded in the dielectric layer 113. The dielectric layer 113 can correspond to a front side 112 of the first semiconductor structure 110, the substrate 111 defines a backside of the first semiconductor structure 110, and the bond pads 114 can be exposed at the front side 112. The first semiconductor structure 110 can be a chip or other component that is singulated from a larger die or a wafer to have a cross-sectional dimension W1. The singulation process (e.g., dicing) may form an edge surface 115 of the first semiconductor structure 110 that is smooth or otherwise has a dicing signature (e.g., planar planar/side surface, sawing marks/artifacts, and the like).

FIG. 1B is a schematic, cross-sectional side view of an example second semiconductor structure 120. The second semiconductor structure 120 includes a substrate 121 (e.g., a silicon substrate), a dielectric layer 123 (e.g., a silicon oxide layer) on the substrate 121, and a plurality of bond pads 124 (e.g., copper bond pads), one or more dummy pads 126, and a probing pad 128 embedded in the dielectric layer 123. The dielectric layer 123 can correspond to a front side 122 of the second semiconductor structure 120, the substrate 121 defines a backside of the second semiconductor structure 120, and the bond pads 124 and the dummy pads 126 can be exposed at the front side 122. The probing pad 128 can be positioned adjacent to the substrate 121 such that the probing pad 128 is initially covered by the dielectric layer 123 and not exposed at the front side 122. The second semiconductor structure 120 can be a wafer or other component with a cross-sectional dimension W2.

To expose the probing pad 128 embedded in the dielectric layer 123, a portion of the dielectric layer 123a surrounding the probing pad 128 can be removed via various means. For example, an etching tool 130 can be used with a photomask 140 positioned to generally cover the bonding pads 124 and, in some cases, the dummy pads 126, to remove the portion of the dielectric layer 123a and thereby expose the probing pad 128. The etching tool 130 can be a physical etching tool or a chemical etching tool. In some cases, the etching process leaves a portion of the dielectric layer 123b around the probing pad 128 and on the substrate 121 remaining. Moreover, the etching process can create an edge surface 125 that may be curved (as shown) or generally flat.

FIG. 1C is a schematic, cross-sectional side view of an example semiconductor device assembly 100 including the first semiconductor structure 110 and the second semiconductor structure 120. As shown, the first semiconductor structure 110 is stacked on top of the etched second semiconductor structure 120 in a face-to-face arrangement such that the front side 112 of the first semiconductor structure 110 interfaces the front side 122 of the second semiconductor structure 120, and the bond pads 114 can be coupled to the bond pads 124 via, for example, hybrid bonding. Also, the cross-sectional dimension W1 of the first semiconductor structure 110 can be less than the cross-sectional dimension W2 of the second semiconductor structure 120 such that a portion of the second semiconductor structure 120, including the probing pad 128, extends past the edge surface 115 and does not interface the first semiconductor structure 110 to remain exposed. The dummy pads 126 may or may not interface the first semiconductor structure 110.

Fabricating the semiconductor device assembly 100 as illustrated in and described above with reference to FIGS. 1A-IC can result in the semiconductor device assembly 100 having a discontinuous edge surface or lateral offsets between the surfaces 115 and 125, as shown in FIG. 1C. This may be attributable to the small size scale of the semiconductor device assembly 100, the precision limits of the singulation equipment used to dice the first semiconductor structure 110, and the alignment tool used to stack the first and second semiconductor structures 110, 120. Moreover, even if the edge surfaces 115, 125 are somehow aligned, the flat shape of the edge surface 115 and the curved shape of the edge surface 125 cannot form a smooth edge surface.

Various embodiments of the present application provide fabrication methods and resulting semiconductor device assemblies that utilize self-aligning process. For example, a semiconductor package can include a narrower/smaller die bonded over a wider die/substrate. The top die can be used as a mask to pattern or expose components on the extended or uncovered portion of the bottom die/substrate. In other words, instead of stacking and bonding the semiconductor structures after etching the larger semiconductor structure, the semiconductor structures may be stacked and bonded together first, then etched together. The resulting semiconductor device assembly can have artifacts that indicate the different fabrication method involved, such as a continuous edge surface that is smooth and otherwise uninterrupted across the stacked devices.

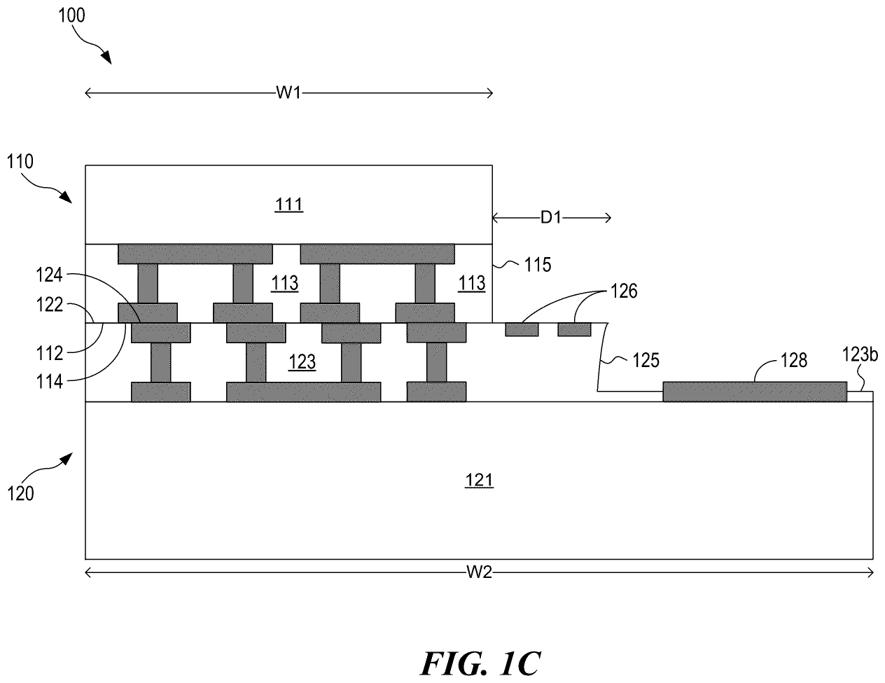

FIG. 2 is a schematic, cross-sectional side view of a semiconductor device assembly 200 (“the assembly 200”) in accordance with embodiments of the present technology. The assembly 200 can include a first semiconductor structure 210 (e.g., a chip, a wafer) and a second semiconductor structure 220 (e.g., a chip, a wafer) attached or bonded to the first semiconductor structure 210. The assembly 200 can be a chip-to-wafer assembly, a chip-to-chip assembly, a wafer-to-wafer assembly, etc. In some embodiments, the first semiconductor structure 210 comprises a logic chip, such as a processor or a neuromorphic computer and/or memory. In some embodiments, the second semiconductor structure 220 comprises a memory wafer (e.g., a NAND memory wafer).

The first semiconductor structure 210 includes a first substrate 211 (e.g., a silicon substrate), a first dielectric layer 213 (e.g., a silicon oxide layer) coupled to the first substrate 211, and a plurality of first bond pads 214 (e.g., copper bond pads) embedded in the first dielectric layer 213. The first dielectric layer 213 can correspond to a first front side 212 of the first semiconductor structure 210, the first substrate 211 can define a back side of the first semiconductor structure 210, and the first bond pads 214 can be exposed at the first front side 212 (prior to bonding). The first semiconductor structure 210 can have a cross-sectional dimension W3.

The second semiconductor structure 220 includes a second substrate 221 (e.g., a silicon substrate), a second dielectric layer 223 (e.g., a silicon oxide layer) coupled to the substrate 221, and a plurality of second bond pads 224 (e.g., copper bond pads), and a probing pad 228 (e.g., an aluminum pad). The second dielectric layer 223 can correspond to a second front side 222 of the second semiconductor structure 220, the second substrate 221 can define a back side of the second semiconductor structure 220, and the second bond pads 224 can be exposed at the second front side 222 (prior to bonding). The probing pad 228 can be positioned adjacent to the substrate 221 and surrounded by a portion of the second dielectric layer 223b. The second semiconductor structure 220 can have a cross-sectional dimension W4 that may be about 5 mm, 6 mm, 7 mm, 8 mm, 9 mm, or 5-9 mm. The probing pad 228 can have a cross-sectional dimension D5 that may be about 50 μm, 55 μm, 60 μm, 65 μm, 70μ, 75μ, 80 μm, or 50-80 μm.

In the illustrated embodiment, the first semiconductor structure 210 is stacked on top of the second semiconductor structure 220 in a face-to-face arrangement such that the first front side 212 interfaces the second front side 222, and the first bond pads 214 can be coupled/connected to the second bond pads 224 via, for example, hybrid bonding. Also, the cross-sectional dimension W3 of the first semiconductor structure 210 can be less than the cross-sectional dimension W4 of the second semiconductor structure 220 such that a portion of the second semiconductor structure 220 with cross-sectional dimension D2, including the probing pad 228, extends past the first substrate 211 and does not interface the first semiconductor structure 210 to remain exposed. The cross-sectional dimension D2 can be about 110 μm, 115 μm, 120 μm, 125 μm, 130 μm, 135 μm, 140 μm, or 110-140 μm.

The first substrate 211 can have a straight, vertical, and flat edge 217. The first dielectric layer 213 can have a first vertically oriented surface 225a, and the second dielectric layer 223 can have a second vertically oriented surface 225b. The first and second vertically oriented surfaces 225a, 225b can form a shared, curved, continuous, and smooth edge surface 225. The edge surface 225 can be continuous such that the peripheral portions of the first and second vertically oriented surfaces 225a, 225b that abut each other (i) lie on the same plane (e.g., do not form a step), (ii) have the slope (e.g., do not form an edge), and (iii) maintain the same surface gradient pattern (e.g., the pattern of the change in slope) across. The edge surface 225 can extend between the first substrate 211 and the portion of the second dielectric layer 223b remaining on the second substrate 221 across a vertical distance D3, and can curve inward into the first and second dielectric layers 213, 223 across a horizontal distance D4 to define an undercut. In other words, a peripheral portion of the first substrate 211 (e.g., about the flat edge 217) can form an overhang with the edge surface 225 having a continuously concave shape under the first substrate 211. The edge surface 225 can face the probing pad 228, as shown. In some embodiments, the ratio between the horizontal distance D4 and the vertical distance D3 of the edge surface 225 (e.g., a width-to-height ratio of the undercut) is about 6%, 8%, 10%, 12%, 14%, 6-14%, or 8-12%.

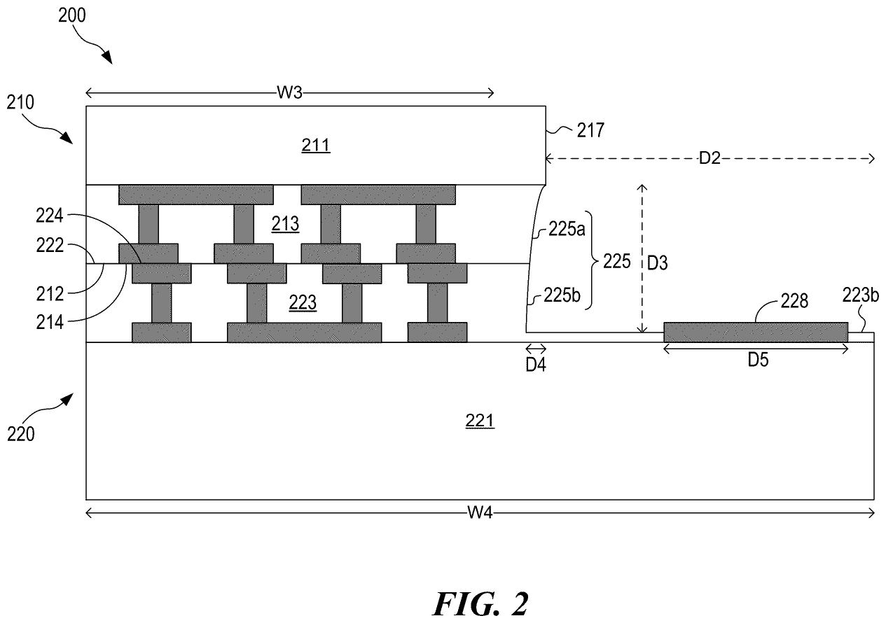

FIG. 3 is a schematic, cross-sectional side view of another semiconductor device assembly 300 (“the assembly 300”) in accordance with embodiments of the present technology. The assembly 300 is generally similar to the assembly 200 illustrated in FIG. 2. For example, the assembly 300 includes the first semiconductor structure 210 and a second semiconductor structure 320. The second semiconductor structure 320 can share similarities with the second semiconductor structure 220 of FIG. 2, such as by having the second dielectric layer 223 forming the shared edge surface 225 with the first dielectric layer 213. In addition, however, the second semiconductor structure 320 includes one or more dummy pads 326 that are vertically aligned with the bond pads 224 and horizontally positioned beyond the first semiconductor structure 210 (e.g., to the right of the first substrate 211 in FIG. 3). Individual ones of the dummy pads 326 are supported by corresponding plateau-shaped portions 328 of the second dielectric layer 223. In other words, the dummy pads 326 and the corresponding portions of the second dielectric layer 223 can form mesas. As shown, the plateau-shaped portions 328 can be connected at and extend from the portion of the dielectric layer 223b extending over the second substrate 221. Also, each of the plateau-shaped portions 328 can have a curved surface such that each dummy pad 326 is supported at the upper narrow part of the plateau-shaped portion 328. In some embodiments, the curvature of the curved surface of each plateau-shaped portion 328 corresponds to the curvature of the edge surface 225. In other embodiments, the curvatures are different.

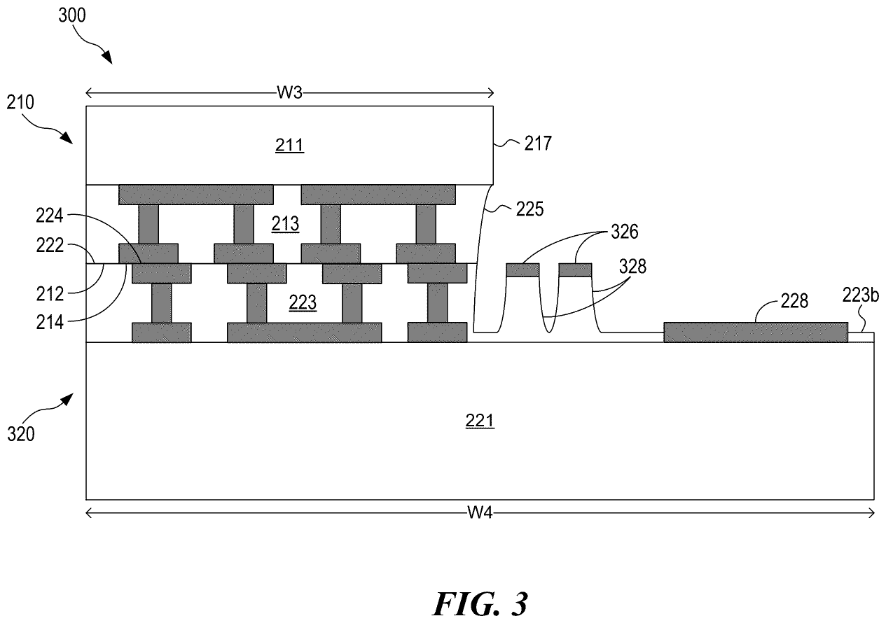

FIG. 4 is a schematic, cross-sectional side view of a packaged semiconductor device assembly 400 (“the assembly 400”) in accordance with embodiments of the present technology. In the illustrated embodiment, the assembly 400 includes the assembly 200 (FIG. 2) stacked on a top surface of a package substrate 420, which is coupled to a printed circuit board (PCB) 430 via a plurality of connectors 425 (e.g., solder). The assembly 200 can be attached to the package substrate 420 via a tape 424 (e.g., back grinding tape) or other adhesive structures. The package substrate 420 can include a pad 422 thereon and exposed on the top surface. The exposed probing pad 228 can be electrically coupled to the pad 422, such as via a wire 402 extending therebetween. The assembly 400 can also include an encapsulant 410 (e.g., a mold, an epoxy, or other resin based structure) on the top surface of the package substrate 420 that encapsulates all or at least a part of the assembly 200 and the wire 402. In other embodiments, the assembly 400 can include the assembly 300 (FIG. 3) in place of the assembly 200.

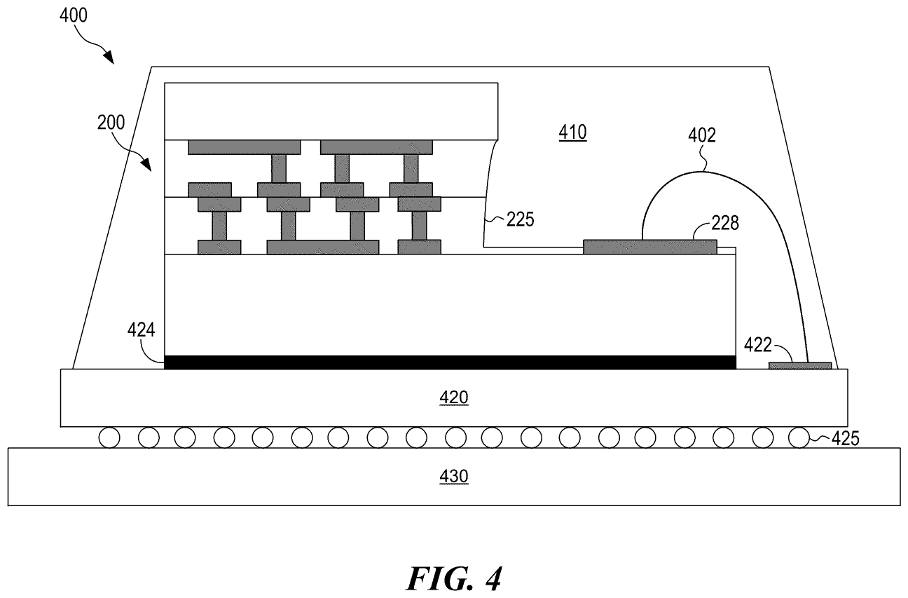

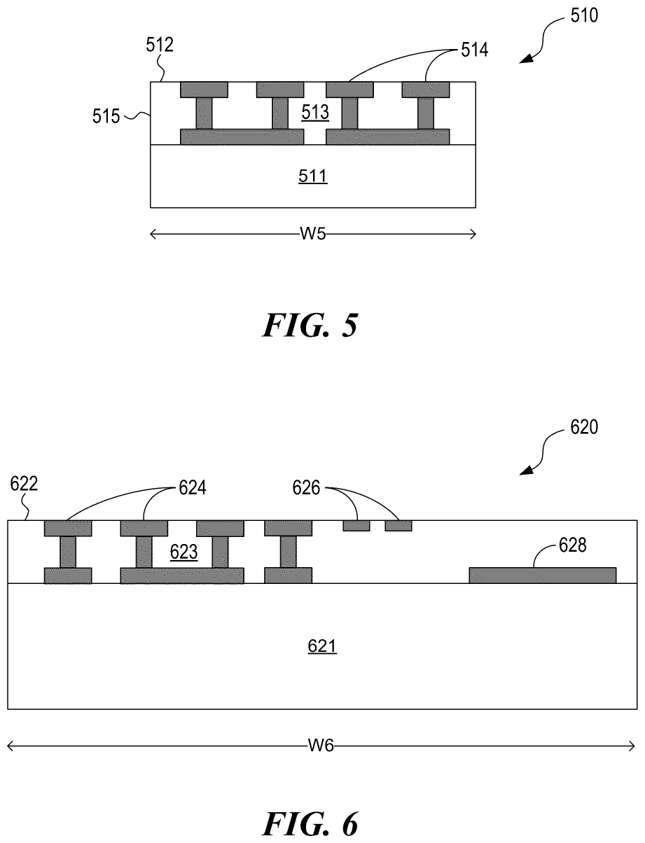

FIGS. 5-8 are schematic, cross-sectional side views illustrating a series of fabrication steps of semiconductor device assemblies in accordance with embodiments of the present technology. First, a first semiconductor structure 510 and a second semiconductor structure 620 are provided, as seen in FIGS. 5 and 6, respectively. Referring first to FIG. 5, the first semiconductor structure 510 includes a substrate 511, a dielectric layer 513 coupled to the substrate 511, and a plurality of bond pads 514 embedded in the dielectric layer 513. The bond pads 514 can be exposed at a front side 512 of the first semiconductor structure 510. The first semiconductor structure 510 can be singulated to have a cross-sectional dimension W5, and can have an edge surface 515 with a dicing signature (e.g., smooth, flat). In some embodiments, the first semiconductor structure 510 can correspond to a logic device.

Referring next to FIG. 6, the second semiconductor structure 620 (e.g., a memory device, such as a NAND wafer or chip) can include a substrate 621, a dielectric layer 623 coupled to the substrate 621, and a plurality of bond pads 624 and a probing pad 628 embedded in the dielectric layer 623. The second semiconductor structure 620 may also include one or more dummy pads 626 embedded in the dielectric layer 623. The bond pads 624 and the dummy pads 626 can be exposed at a front side 622 of the second semiconductor structure 620. The probing pad 628 can be positioned adjacent to the substrate 621 such that the probing pad 628 is not exposed to the front side 622 (e.g., covered by the dielectric layer 623 instead). The second semiconductor structure 620 can have a cross-sectional dimension W6. Notably, in contrast to the second semiconductor structure 120 illustrated in FIG. 1B, the second semiconductor structure 620 is not etched or otherwise subjected to selective dielectric removal independently of the first semiconductor structure 510.

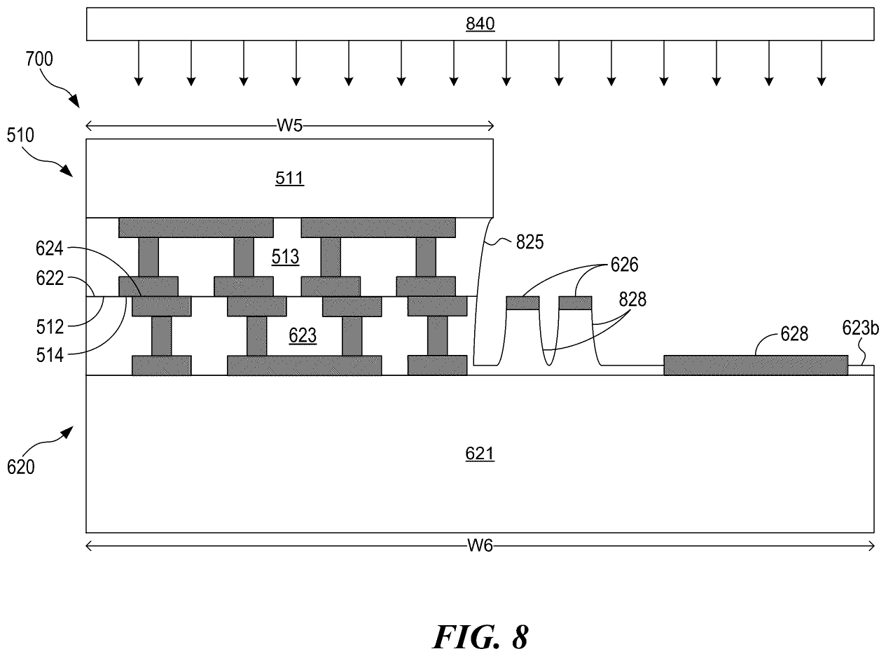

In some embodiments, when fabricating the first and/or second semiconductor structures 510, 620, a silicon nitride layer can be applied to serve as an etch stop layer. For example, the silicon nitride layer can allow the portion of the dielectric layer 623b (FIG. 8) to remain during the etching process. In some embodiments, forming the dielectric layers 513, 623 includes depositing silicon oxide, performing chemical mechanical polishing of the silicon oxide, depositing a set of sandwich layers comprising silicon carbon nitride (e.g., in the form of a thin film), silicon oxide, and silicon carbon nitride (e.g., in the form of a thin film), and forming the bond pads 514, 624. In some embodiments, fabricating the first and/or second semiconductor structures 510, 620 further includes forming vias (e.g., through-silicon vias).

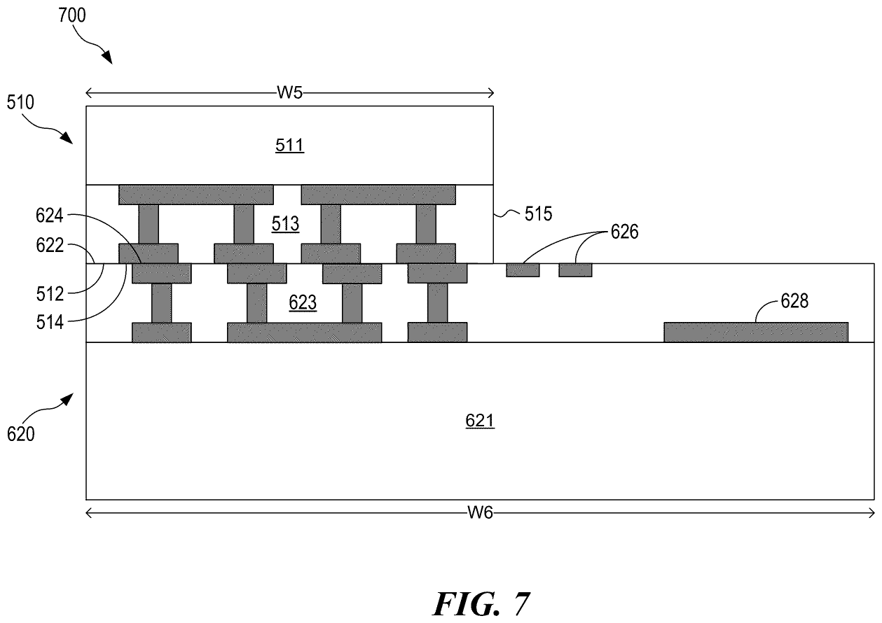

Referring next to FIG. 7, the first semiconductor structure 510 is stacked on top of and coupled to the second semiconductor structure 620 to form a semiconductor device assembly 700 (“the assembly 700”). More specifically, the first and second semiconductor structures 510, 620 are positioned and oriented in a face-to-face arrangement such that the front side 512 interfaces the front side 622, and the bonds pads 514, 624 are bonded together via, for example, hybrid bonding. In some embodiments, the bonding process can cause the dielectric layers 513 and 623 and/or the bond pads 514 and 624 to directly connect (e.g., fusion bond) to each other, such as through pressure, heat, vibration, and/or the like. Furthermore, as shown, the cross-sectional dimension W5 of the first semiconductor structure 510 is less than the cross-sectional dimension W6 of the second semiconductor structure 620 such that the dummy pads 626 are exposed without interfacing the first semiconductor structure 510 and the probing pad 628 is positioned horizontally apart from the first semiconductor structure 510. In some embodiments, one or more of the dummy pads 626 interface the first semiconductor structure 510 and thus are not exposed.

Referring next to FIG. 8, the assembly 700 can be subjected to an etching (e.g., dry etching) process or other selective dielectric removal process. For example, an etching tool 840 can be positioned over the assembly 700. Notably, unlike in FIG. 1B, a separate photomask is not used during the etching process. Instead, the substrate 511 forming the backside of the first semiconductor structure 510 effectively acts as a mask during the etching process. Therefore, upon completion of the etching process, the dielectric layer 513 of the first semiconductor structure 510 and the dielectric layer 623 of the second semiconductor structure 620 can have a shared, continuous, and smooth edge surface 825. Moreover, in some embodiments, the shared vertically oriented surface 825 can have a curved shape that is concave or indented inwards toward the center portion of the substrate 511 as a result of such etching process. The edge surface 825 can extend between the substrate 511 and a portion of the dielectric layer 623b remaining on the substrate 621, and can curve inward into the dielectric layers 513, 623.

Furthermore, as shown in FIG. 8, each dummy pad 626 is supported by a corresponding plateau-shaped portion 828 of the dielectric layer 623. The plateau-shaped portions 828 can be connected at and extend from the portion of the dielectric layer 623b extending over the substrate 621. Also, each of the plateau-shaped portions 828 can have a curved surface such that each dummy pad 626 is supported at the upper narrow part of the plateau-shaped portion 828. In some embodiments, the curvature of the curved surface of each plateau-shaped portion 828 corresponds to the curvature of the edge surface 825. In other embodiments, the curvatures are different.

As similarly discussed above with reference to FIG. 2, the assembly 700 can be a chip-to-wafer assembly, a chip-to-chip assembly, a wafer-to-wafer assembly, etc. The edge surface 825 comprises an artifact of the fabrication method described above in which the assembly 700 is etched after aligning, stacking, and bonding of the first and second semiconductor structures 510, 620.

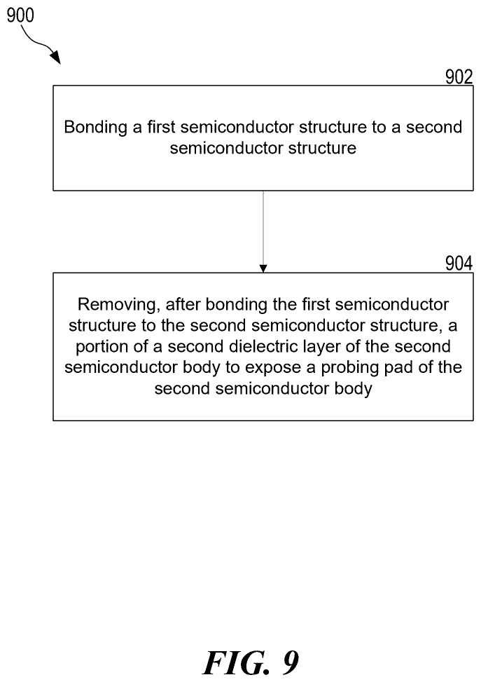

FIG. 9 is a flowchart illustrating a method 900 of making a semiconductor device assembly in accordance with embodiments of the present technology. While the method 900 is described below with reference to FIGS. 2-8, a person skilled in the art will appreciate that the method 900 can be practiced with and/or to form other embodiments of semiconductor device assemblies. Moreover, unless specified otherwise, one or more of the steps of the method 900 can be performed in a different order or can be omitted, and/or the method 900 can be supplemented with additional steps.

The method 900 begins at block 902 by bonding a first plurality of bonding pads (e.g., the bonding pads 514) of a first semiconductor structure (e.g. the first semiconductor structure 510) to a second plurality of bonding pads (e.g., the bonding pads 624) of a second semiconductor structure (e.g., the second semiconductor structure 620). The bonding can be via hybrid bonding, oxide bonding, copper bonding, and/or other suitable bonding techniques. In some embodiments, the first semiconductor structure comprises a logic chip and the second semiconductor structure comprises a NAND wafer.

At block 904, the method 900 continues by removing, after bonding the semiconductor structures, a portion of a second dielectric layer (e.g., the portion of the dielectric layer 623b) of the second semiconductor structure to expose a probing pad (e.g., the probing pad 628) of the second semiconductor structure. In some embodiments, removing the portion of the second dielectric layer of the second semiconductor structure comprises etching using a first silicon substrate (e.g., the substrate 511) of the first semiconductor structure as a mask. In some embodiments, removing the portion of the second dielectric layer of the second semiconductor structure comprises etching without a mask distinct from the first semiconductor structure or the second semiconductor structure.

In some embodiments, the removed portion of the second dielectric layer includes a side edge portion of the second dielectric layer, and the method 900 continues by removing a side edge portion of a first dielectric layer of the first semiconductor structure. In some embodiments, a remaining portion of the first dielectric layer and a remaining portion of the second dielectric layer form a continuous surface (e.g., the edge surface 825). In some embodiments, the continuous surface comprises a curved continuous surface.

In some embodiments, removing the portion of the second dielectric layer of the second semiconductor structure leaves plateau-shaped portions (e.g., the plateau-shaped portions 828) of the second dielectric layer underneath one or more dummy pads (e.g., the dummy pads 626) of the second semiconductor structure. In some embodiments, the plateau-shaped portions of the second dielectric layer include curved side surfaces.

In some embodiments, the method 900 continues by coupling a second silicon substrate of the second semiconductor structure to a package substrate (e.g., the package substrate 420), connecting a wire (e.g., the wire 402) between the probing pad of the second semiconductor structure and the package substrate, and encapsulating the first semiconductor structure, the second semiconductor structure, and the wire in an encapsulant (e.g., the encapsulant 410).

The semiconductor device assemblies and the associated fabrication methods disclosed herein remove the need to precisely align different semiconductor structures (e.g., chips and wafers) and the need for a separate photomask during the etching process. Instead, the assemblies disclosed herein are etched after the bonding process and by using one of the semiconductor structures as the mask. Thus, embodiments of the present technology enable self-aligned patterning for hybrid bonding probe integration and wire bonding on package substrates for various semiconductor structures, such as NAND memory, logic chips (e.g., foundry shuttle logic), neuromorphic architectures, etc.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a first semiconductor structure including:
a first silicon substrate having a first lateral dimension;
a first dielectric layer on the first silicon substrate, the first dielectric layer having a first vertically oriented surface extending from a peripheral edge of the first silicon substrate; and
a first plurality of pads embedded in the first dielectric layer and exposed on a front side of the first semiconductor structure; and
a second semiconductor structure under and attached to the first semiconductor structure, the second semiconductor structure including:
a second silicon substrate having a second lateral dimension greater than the first lateral dimension;
a second dielectric layer on the second silicon substrate, the second dielectric layer having a second vertically oriented surface;
a second plurality of pads (1) embedded in the second dielectric layer, (2) exposed on a front side of the second semiconductor structure, and (3) connected to the first plurality of pads; and
a probing pad on the second silicon substrate and closer to the second silicon substrate than the second plurality of pads, wherein the second vertically oriented surface is between the probing pad and the second plurality of pads,
wherein the probing pad, the first vertically oriented surface, and the second vertically oriented surface are exposed, and
wherein the first and second vertically oriented surfaces form a continuous surface.

2. The semiconductor device of claim 1, wherein the continuous surface comprises a curved continuous surface.

3. The semiconductor device of claim 2, wherein the curved continuous surface defines an undercut below the first silicon substrate.

4. The semiconductor device of claim 1, wherein the second semiconductor structure further includes one or more dummy pads located between the second plurality of pads and the probing pad, wherein individual ones of the dummy pads are supported by corresponding plateau-shaped portions of the second dielectric layer.

5. The semiconductor device of claim 4, wherein the plateau-shaped portions of the second dielectric layer include curved side surfaces.

6. The semiconductor device of claim 1, wherein the exposed side edge of the first dielectric layer and the exposed side edge of the second dielectric layer forming the continuous surface face the probing pad.

7. The semiconductor device of claim 1, further comprising:
a package substrate coupled to a backside of the second semiconductor structure and having a pad thereon;
a wire extending between the probing pad of the second semiconductor structure and the pad of the package substrate; and
an encapsulant supported by the package substrate, wherein the first semiconductor structure, the second semiconductor structure, and the wire are embedded in the encapsulant.

8. The semiconductor device of claim 1, wherein a distance between a side edge of the first silicon substrate and a side edge of the second silicon substrate is between 110-140 μm.

9. The semiconductor device of claim 1, wherein the first semiconductor structure comprises a logic chip.

10. The semiconductor device of claim 1, wherein the second semiconductor structure comprises a NAND device.

11. A method of fabricating a semiconductor device, the method comprising:
bonding a first semiconductor structure to a second semiconductor structure; and
removing, after bonding the first semiconductor structure to the second semiconductor structure, a portion of a second dielectric layer of the second semiconductor structure to expose a probing pad of the second semiconductor structure.

12. The method of claim 11, wherein removing the portion of the second dielectric layer of the second semiconductor structure comprises etching a portion of the second semiconductor structure using a backside of the first semiconductor structure as a mask.

13. The method of claim 11, wherein the removed portion of the second dielectric layer includes a side edge portion of the second dielectric layer, the method further comprising:
removing a side edge portion of a first dielectric layer of the first semiconductor structure.

14. The method of claim 13, wherein removing includes forming a continuous surface oriented vertically and extending continuously across the first dielectric layer and the second dielectric layer.

15. The method of claim 14, wherein the continuous surface comprises a curved continuous surface.

16. The method of claim 11, wherein removing includes forming plateau-shaped portions of the second dielectric layer underneath one or more dummy pads of the second semiconductor structure.

17. The method of claim 16, wherein the plateau-shaped portions of the second dielectric layer include curved side surfaces.

18. The method of claim 11, wherein removing includes etching after bonding the first and second semiconductor structures and without a mask distinct from the first semiconductor structure or the second semiconductor structure.

19. The method of claim 11, further comprising:
attaching the second semiconductor structure to a package substrate having a pad thereon;
connecting a wire between the probing pad and the pad of the package substrate; and
encapsulating the first semiconductor structure, the second semiconductor structure, and the wire in an encapsulant.

20. The method of claim 11, wherein the first semiconductor structure comprises a logic chip, and wherein the second semiconductor structure comprises a NAND device.
